(19) United States
(12) Patent Application Publication
(10) Pub. No.: US 2026/0188156 A1
(43) Pub. Date: Jul. 2, 2026

(54) Light Emitting Display Apparatus

(71) Applicant: LG Display Co., Ltd., Seoul (KR)

(72) Inventors: Minseok Kim, Paju-si (KR); YeongRae Seo, Paju-si (KR)

(21) Appl. No.: 19/391,674

(22) Filed: Nov. 17, 2025

(30) Foreign Application Priority Data
Dec. 31, 2024 (KR) 10-2024-0202303

(51) Int. Cl. G09G 3/00; G09G 3/32; G09G 3/3266; H10H 20/819; H10H 29/41; H10H 29/49; H10H 29/80; H10H 29/853; H10K 59/124; H10K 59/131; H10K 59/80

(52) U.S. Cl. CPC G09G 3/006; G09G 3/32; G09G 3/3266; H10H 20/819; H10H 29/41; H10H 29/49; H10H 29/842; H10H 29/853; H10K 59/124; H10K 59/131; H10K 59/873; G09G 2310/0267; G09G 2310/0286; G09G 2330/12

(57) ABSTRACT

A light emitting display apparatus presented herein comprises a substrate including a display area and a non-display area, a pixel circuit layer including a pixel driving line including a gate line and a data line configured at the display area, and a pixel circuit connected to the gate line and the data line, an overcoat layer at the display area that covers the pixel circuit layer, a light emitting device layer on the overcoat layer and connected to the pixel circuit, a gate driving circuit at the non-display area and connected to the gate line, and a plurality of test lines disposed at a corner portion of the substrate and connected to the gate driving circuit. An end of each of the plurality of test lines is exposed to an outer side surface of the substrate, and each of the plurality of test lines includes a line disconnection part.

### CROSS-REFERENCE TO RELATED APPLICATION

The present application claims priority to Republic of Korea Patent Application No. 10-2024-0202303 filed on Dec. 31, 2024, which is hereby incorporated by reference in its entirety.

### BACKGROUND

### Field

The present disclosure relates to a light emitting display apparatus.

### Description of Related Art

A light emitting display apparatus is self-luminous display devices that do not require a separate light source, unlike liquid crystal display apparatus, so the light emitting display apparatus may be manufactured in a lightweight and thin manner. In addition, the light emitting display apparatus is in the spotlight as next-generation display apparatus because they are advantageous in terms of power consumption by driving low voltage and have excellent color arrangement, response speed, viewing angle, and contrast ratio.

The light emitting display apparatus displays an image through light emission of a light emitting device layer including a light emitting device interposed between two electrodes. In this case, light generated according to light emission of the light emitting device is emitted to the outside through a substrate or the like.

The light emitting display apparatus includes a plurality of pixels provided in the display area of the substrate, and each of the plurality of pixels is configured in pixel areas provided by a plurality of gate lines and a plurality of data lines. A gate driving circuit connected to the plurality of gate lines is disposed in the non-display area of the substrate. The gate driving circuit includes a test line for an inspection process performed before a light emitting device layer and an encapsulation part are formed. However, in a trimming (or a grinding) process subsequently performed after the inspection process, a part of the test line is exposed. Hydrogen and moisture penetrate through the exposed part of the test line, causing lifting of the encapsulation part and deterioration of the light emitting display apparatus or a light emitting device.

### SUMMARY

In order to solve the above-described problems, the inventors of the present disclosure have conducted continuous various experiments, and through the various experiments, invented a light emitting display apparatus having a new structure capable of preventing penetration of hydrogen and moisture.

One or more embodiments of the present disclosure are directed to providing a light emitting display apparatus capable of preventing penetration of hydrogen and moisture.

One or more embodiments of the present disclosure are directed to providing a light emitting display apparatus with improved reliability.

Additional features, advantages, and embodiments of the present disclosure are set forth in part in the present disclosure and will also be apparent from the present disclosure or may be learned by practice of the inventive concepts provided herein. Other features, advantages, and embodiments of the present disclosure may be realized and attained by the descriptions provided in the present disclosure, and claims hereof as well as the appended drawings, or derivable therefrom.

To achieve these and other advantages and embodiments of the present disclosure, as embodied and broadly described herein, in one or more embodiments, a light emitting display apparatus may comprise a substrate including a display area and a non-display area, a pixel circuit layer including a pixel driving line including a gate line and a data line configured at the display area, and a pixel circuit connected to the gate line and the data line, an overcoat layer configured at the display area to cover the pixel circuit layer, a light emitting device layer configured on the overcoat layer and connected to the pixel circuit, a gate driving circuit configured at the non-display area and connected to the gate line, and a plurality of test lines disposed at a corner portion of the substrate and connected to the gate driving circuit. An end of each of the plurality of test lines may be exposed to an outer side surface of the substrate, and each of the plurality of test lines may include a line disconnection part formed between the end of each of the plurality of test lines and the gate driving circuit.

Details of other embodiments will be included in the detailed description of the disclosure and the accompanying drawings.

According to one or more embodiments of the present disclosure, the light emitting display apparatus includes the line disconnection part, and thus, a moisture permeable path of the light emitting display apparatus is blocked, penetration of hydrogen and moisture may be prevented, and deterioration of the light emitting display apparatus or a light emitting device may be prevented.

According to one or more embodiments of the present disclosure, the light emitting display apparatus with improved reliability may be provided, a long lifespan may be realized, and low-power driving may be possible.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims.

Further embodiments and advantages are discussed below in conjunction with embodiments of the present disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the present disclosure and together with the description serve to explain principles of the disclosure. However, the technical features of the present disclosure are not limited to those shown in the specific drawings, and the features disclosed in each drawing may be combined to form a new embodiment.

FIG. 1 is a plan view illustrating a light emitting display apparatus according to one or more embodiments of the present disclosure.

FIG. 2 is an exemplary diagram illustrating a structure of a gate driving circuit applied to a light emitting display apparatus according to one or more embodiments of the present disclosure.

FIG. 3 is a cross-sectional view taken along line I-I′ of FIG. 2.

FIG. 4 is an enlarged view schematically illustrating portion ‘A’ illustrated in FIG. 1.

FIG. 5 is a cross-sectional view taken along line II-II′ of FIG. 4 according to one or more embodiments of the present disclosure.

FIG. 6 is a cross-sectional view taken along line II-II′ of FIG. 4 according to one or more other embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Advantages and features of the present disclosure, and implementation methods thereof, are clarified through the embodiments described with reference to the accompanying drawings. The present disclosure may, however, be embodied in different forms and should not be construed as limited to the example embodiments set forth herein. Rather, these example embodiments are examples and are provided so that this disclosure may be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. In addition, in a situation where “comprise,” “have,” and “include” described in the present disclosure are used, another part may be added unless “only” is used. The terms of a singular form can include plural forms unless referred to the contrary.

In construing an element, the element is construed as including an error range although there is no explicit description.

In describing a position relationship, for example, when a position relation between two parts is described as “on”, “over”, “under”, “next”, and “adjacent to” or the like, one or more other parts may be located between the two parts unless a more limiting term, such as “immediate(ly)”, “direct(ly)”, or “close(ly)” is used.

In describing a time relationship, for example, when the temporal order is described as, for example, “after”, “subsequent”, “next”, and “before”, or the like, a case that is not continuous may be included unless a more limiting term, such as “just”, “immediate(ly)”, or “direct(ly)” is used.

It will be understood that, although the terms “first”, “second”, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

In describing elements of the present disclosure, the terms “first”, “second”, “A”, “B”, “(a)”, “(b)”, etc. may be used. These terms are intended to identify the corresponding elements from the other elements, and basis, order, or number of the corresponding elements should not be limited by these terms. The expression that an element or layer is “connected”, “coupled”, or “adhered” to another element or layer means the element or layer may not only be directly connected or adhered to another element or layer, but also be indirectly connected or adhered to another element or layer with one or more intervening elements or layers “disposed” or “interposed” between the elements or layers, unless otherwise specified.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art may sufficiently understand. Embodiments of the present disclosure may be carried out independently from each other, or may be carried out together in co-dependent relationship.

Hereinafter, embodiments of a light emitting display apparatus according to the present disclosure will be described in detail with reference to the accompanying drawings. For convenience of description, a scale of each of elements illustrated in the accompanying drawings may differ from a real scale, and thus, is not limited to a scale illustrated in the drawings.

The light emitting display apparatus according to one or more embodiments of the present disclosure may be a flexible light emitting display apparatus, a light emitting display panel, or a flexible light emitting display panel, but embodiments of the present disclosure are not limited thereto. For example, the light emitting display apparatus according to one or more embodiments of the present disclosure may include a set electronic apparatus or a set device (or a set apparatus) such as a notebook computer, a television, a computer monitor, an equipment apparatus including a light emitting display apparatus for vehicles (or an automotive) or another type apparatus for vehicles, or a mobile electronic apparatus such as a smartphone or an electronic pad and or the like, which is a complete product (or a final product) including a light emitting display panel.

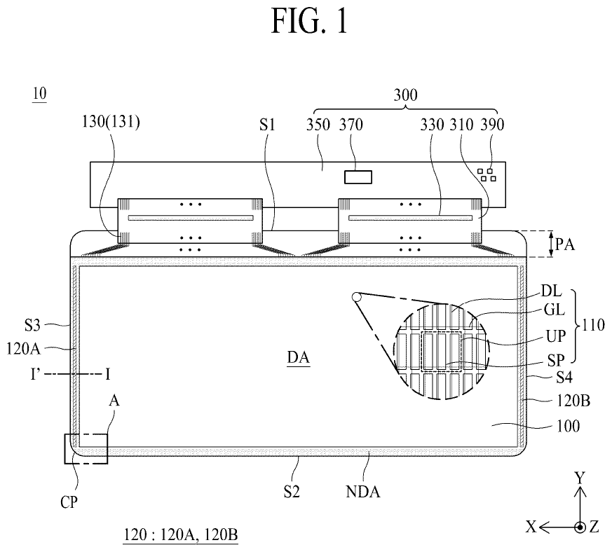

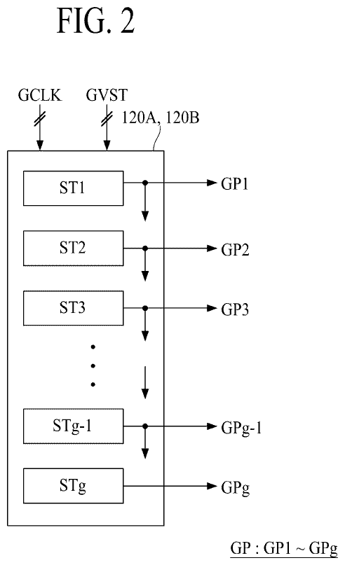

FIG. 1 is a plan view illustrating a light emitting display apparatus according to one or more embodiments of the present disclosure. FIG. 2 is an exemplary diagram illustrating a structure of a gate driving circuit applied to a light emitting display apparatus according to one or more embodiments of the present disclosure.

Referring to FIGS. 1 and 2, a light emitting display apparatus (or light emitting display panel) 10 according to one or more embodiments of the present disclosure may include a substrate 100 having a display area DA, a non-display area NDA, and a pad area PA.

The display area DA may be an area which displays an image, and may be a pixel array area, an active area, a pixel array part, a display part, or a screen. For example, the display area DA may be disposed at a central portion of the light emitting display apparatus (or the light emitting display panel).

The non-display area NDA may be an area which does not display an image. The non-display area NDA may be a peripheral region of the display area DA. For example, the non-display area NDA may be implemented to surround the display area DA. For example, the non-display area NDA may include an edge portion of the substrate 100. For example, the non-display area NDA may be a non-display part, an inactive area, an inactive part, a peripheral part, or a peripheral area.

The pad area PA may be an extension region extending from one side of the non-display area NDA. The pad area PA may be an area extending from at least a portion of a long-side (or a first long-side) of one side of the non-display area NDA to have a predetermined length along a second direction Y. The pad area PA may include a plurality of data link lines. Each of the plurality of data link lines may electrically connect a plurality of display data pads to a plurality of data lines in a one-to-one correspondence. The pad area PA may include a plurality of gate link lines. Each of the plurality of gate link lines may connect a plurality of display gate pads and the gate driving circuit 120. The pad area PA may correspond to a circuit contact portion, a circuit connection portion, a circuit contact area, a circuit connection area, or a signal input/output area.

According to one or more embodiments of the present disclosure, the substrate 100 may include a first long-side S1, a second long-side S2, a first short-side S3, and a second short-side S4. The first long-side S1 and the second long-side S2 face each other and may be disposed parallel to each other in the second direction Y. The first short-side S3 and the second short-side S4 face each other and may be disposed parallel to each other in the first direction X.

The substrate 100 may further include a corner portion CP. For example, the corner portion CP may be an area between the second long-side S2 and the first short-side S3. For example, the corner portion CP may be a connection portion that connects the second long-side S2 and the first short-side S3. For example, the corner portion CP may be a connection portion that connects the second long-side S2 and the second short-side S4 between the second long-side S2 and the second short-side S4. For example, the corner portion CP may have a curved shape. For example, an end of the corner portion CP may have a predetermined angle and a rounded curved shape. The curved shape may be implemented by grinding or trimming. For example, the corner portion CP may include a curved portion, a connection portion, and a rounding portion.

The light emitting display apparatus (or the light emitting display panel) 10 according to one or more embodiments of the present disclosure may further include a pixel part 110, a gate driving circuit 120, and a plurality of pad parts 130.

The pixel part 110 may be implemented at the display area DA of the substrate 100 and may display a black and white image or a color image. For example, the pixel part 110 may be a pixel layer, a pixel array, a pixel array layer, or a pixel array part.

The pixel part 110 may include a plurality of pixels UP disposed at the display area DA. Each of the plurality of pixels UP may be configured in each pixel areas provided by pixel drive lines. The pixel drive lines may include a plurality of gate lines GL and a plurality of data lines DL configured at the display area DA. Each of the plurality of pixels UP may be implemented at each pixel areas provided by the plurality of gate lines GL and the plurality of data lines DL.

The pixel part 110 may include a light emitting device having an emission structure. For example, the emission structure may include a light emitting layer (or an organic light emitting layer), but is not limited thereto, and the emission structure may include an inorganic light emitting layer (or an inorganic light emitting diode).

Each of the plurality of pixels UP may be configured to implement a black and white image or a color image. One pixel UP may be a unit pixel. Each of the plurality of pixels UP may include a plurality of sub-pixels SP. For example, each of the plurality of sub-pixels SP may be implemented in each sub-pixel areas provided by the pixel drive lines. For example, each of the plurality of sub-pixels SP may be implemented at each sub-pixel areas provided by the plurality of gate lines GL and the plurality of data lines DL. For example, each of the plurality of sub-pixels SP may be configured to implement any one of a plurality of colors (or light) implementing a color image (or color light). For example, each of the plurality of sub-pixels SP may be configured to include a light emitting device implementing any one of red light, green light, blue light, and white light.

The gate driving circuit 120 may be configured at the non-display area NDA. The gate driving circuit 120 may be implemented in the non-display area NDA adjacent to the display area DA to be electrically connected to the plurality of gate lines GL. The gate driving circuit 120 may be implemented in an area (or a first short-side area) of the first short-side S3 and/or an area (or a second short-side area) of the second short-side S4 of the non-display area NDA to be electrically connected to the plurality of gate lines GL. For example, the gate driving circuit 120 may be implemented in one or more of the areas of a pair of short-sides S3 and S4 of the non-display area NDA to be electrically connected to the plurality of gate lines GL.

According to one or more embodiments of the present disclosure, the gate driving circuit 120 may be directly formed or implemented on the substrate 100 by a manufacturing process of thin film transistors of the sub-pixels SP based on a GIP (gate in panel) scheme. For example, the gate driving circuit 120 may be a gate built-in circuit (or an embedded gate circuit) or a gate shift register circuit, but embodiments of the present disclosure are not limited thereto.

The gate driving circuit 120 may supply gate pulses GP1 to GPg to the gate lines GL. When a gate pulse (or a gate on signal) GP generated by the gate driving circuit 120 is supplied to the gate of a transistor which is provided in a subpixel SP, the transistor may be turned on. When a gate off signal generated by the gate driving circuit 120 is supplied to the transistor, the transistor may be turned off.

A gate signal supplied to the gate line GL may include the gate pulse GP and the gate off signal. In order to supply the gate pulses GP1 to GPg to the gate lines GL, the gate driving circuit 120 may include stages ST1 to STg connected to each of the gate lines GL, as illustrated in FIG. 2.

To generate the gate pulses GP1 to GPg, at least one gate start signals GVST generated by a control signal generating part and at least two gate clocks GCLK generated by a shift driver may be transmitted to the gate driving circuit 120. That is, the at least one gate start signals GVST and the at least two gate clocks GCLK may be included in gate control signals.

Any one of the stages ST1 to STg may be driven by the gate start signal GVST to output the gate pulse GP to the gate line GL. The gate pulse GP may be generated by the gate clock GCLK. Each of the remaining stages of the stages ST1 to STg may start operation using a carry signal supplied from a preceding stage, and sequentially generate gate pulses GP to output to the gate lines GL.

According to one or more embodiments of the present disclosure, the gate driving circuit 120 may be configured at the non-display area NDA adjacent to the first short-side S3 of the substrate 100, or may be configured at the non-display area NDA adjacent to the second short-side S4 of the substrate 100.

The gate driving circuit 120 according to one or more embodiments of the present disclosure may include one or more of a first gate driving circuit 120A and a second gate driving circuit 120B.

The first gate driving circuit 120A may be disposed at the non-display area NDA adjacent to the first short-side S3 of the substrate 100. The first gate driving circuit 120A may be configured at a first short-side area of the non-display area NDA adjacent to a first side (or one side) of the display area DA.

The second gate driving circuit 120B may be disposed at the non-display area NDA adjacent to the second short-side S4 of the substrate 100. The second gate driving circuit 120B may be configured at a second short-side area of the non-display area NDA adjacent to a second side (or the other side), which is opposite to the first side, of the display area DA.

According to one or more embodiments of the present disclosure, the first gate driving circuit 120A may be electrically connected to one end of each of the plurality of gate lines GL disposed in the pixel part 110, and the second gate driving circuit 120B may be electrically connected to the other end of each of the plurality of gate lines GL disposed in the pixel part 110.

According to one or more other embodiments of the present disclosure, the first gate driving circuit 120A may be electrically connected to the one end of each odd-numbered (or even-numbered) gate line among the plurality of gate lines GL disposed in the pixel part 110, and the second gate driving circuit 120B may be electrically connected to the other end of each even-numbered (or odd-numbered) gate line among the plurality of gate lines GL disposed in the pixel part 110.

The plurality of pad parts 130 may be implemented in the pad area PA of the substrate 100. The plurality of pad parts 130 may be disposed at a first edge portion adjacent to the first long-side S1 of the substrate 100. The plurality of pad parts 130 may include data pads (or display data pads) connected to the data lines DL and gate pads (or display gate pads) connected to the gate driving circuit 120. The plurality of pad parts 130 may be electrically connected to the pixel circuit. The plurality of pad parts 130 may be electrically connected to the gate driving circuit 120. For example, the plurality of pad parts 130 may be electrically connected to the pixel driving lines for driving the pixel circuit and electrically connected to the gate driving circuit 120.

Each of the plurality of pad parts 130 may be disposed to have a predetermined interval along the first direction X. Each of the plurality of pad parts 130 may include a plurality of pads 131. For example, each of the plurality of pad parts 130 may include a plurality of display data pads, a plurality of pixel driving voltage pads, a plurality of cathode voltage pads, and a plurality of touch data pads. For example, a first pad part connected to the first data line among the plurality of pad parts 130 may further include a plurality of gate pads. In addition, a last pad part connected to the last data line among the plurality of pad parts 130 may further include a plurality of gate pads.

Each of the plurality of gate pads may be electrically connected to the gate driving circuit 120 through a plurality of gate control signal lines (or a plurality of gate link lines) disposed in the pad area PA. For example, the plurality of gate pads disposed in the first pad part may be electrically connected to the first gate driving circuit 120A through the plurality of gate control signal lines disposed in the pad area PA, and the plurality of gate pads disposed in the last pad part may be electrically connected to the second gate driving circuit 120B through the plurality of gate control signal lines disposed in the pad area PA.

The light emitting display apparatus (or the light emitting display panel) according to one or more embodiments of the present disclosure may further include a panel driving circuit part 300.

The panel driving circuit part 300 (or an external panel circuit) may be connected to the pad parts 130 of the light emitting display panel 10. The panel driving circuit part 300 may drive (or emits light) the plurality of pixels UP disposed in the display area DA based on image data supplied from a host driving system, thereby displaying an image corresponding to the image data on the display area DA.

The panel driving circuit part 300 according to one or more embodiments may include a plurality of flexible circuit films 310, a plurality of data driving integrated circuits 330, a printed circuit board 350, a timing control part 370, and a power circuit part 390.

One side edge portion (or an input bonding portion) of each of the plurality of flexible circuit films 310 may be attached to or electrically connected to the printed circuit board 350 through a film attachment process using an anisotropic conductive film. The other side edge portion (or an output bonding portion) of each of the plurality of flexible circuit films 310 may be attached to or electrically connected to the plurality of pad parts 130 of the substrate 100 through a film attachment process using an anisotropic conductive film. Each of the plurality of flexible circuit films 310 may be bent or folded toward a rear surface of the substrate 100 to surround a side surface (or a lateral surface) of the substrate 100. For example, the one side edge portion of each of the plurality of flexible circuit films 310 may be disposed on the rear surface of the substrate 100.

Each of the plurality of data driving integrated circuits 330 may be individually mounted on each of the plurality of flexible circuit films 310. Each of these data driving integrated circuits 330 may receive pixel data and data control signals provided from the timing control part 370, and convert the pixel data into analog pixel data signals for each pixel based on the data control signal to supply to corresponding data lines. For example, the flexible circuit films 310 and the data driving integrated circuits 330 may be referred to as data driving circuits or the like, but are not limited thereto.

The printed circuit board 350 may support the timing control part 370 and the power circuit part 390 and may transfer signals and powers between the components of the panel driving circuit part 300. For example, the printed circuit board 350 may be attached to the rear surface of the substrate 100 using an adhesive member.

The timing control part 370 may be mounted on the printed circuit board 350 and may receive image data and timing synchronization signals which are provided from a host driving system through a user connector disposed on the printed circuit board 350. The timing control part 370 may generate the pixel data by aligning the image data so as to match a pixel arrangement structure in the display area DA based on the timing synchronization signals and provide the generated pixel data to the corresponding data driving integrated circuits 330. In addition, the timing control part 370 may generate data control signals and gate control signals based on the timing synchronization signals, control the driving timing of each of the plurality of data driving integrated circuits 330 through the data control signals, and control the driving timing of the first and second gate driving circuits 120A and 120B through the gate control signals.

The power circuit part 390 may be mounted on the printed circuit board 350 and may generate various voltages necessary for displaying an image on the light emitting display apparatus (or the light emitting display panel) 10 using an input power supplied from the outside and provide the generated voltages to the corresponding circuits.

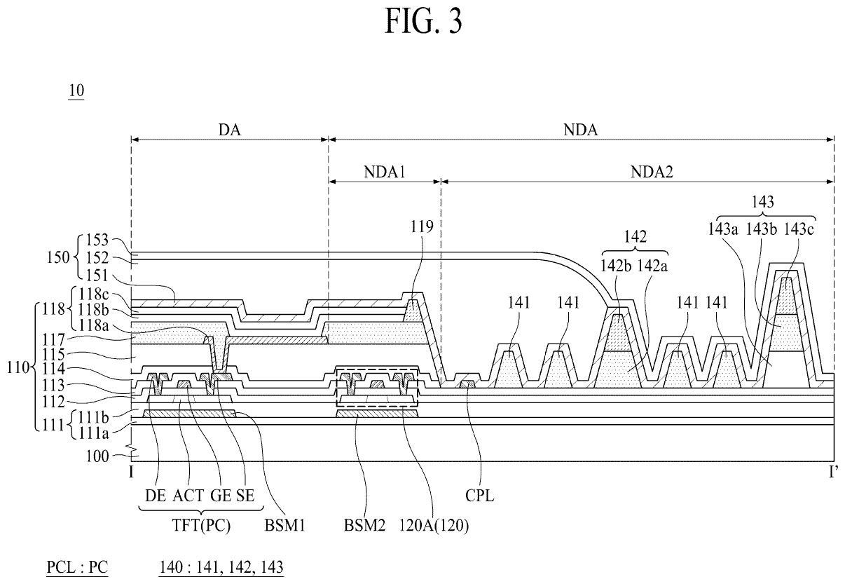

FIG. 3 is a cross-sectional view taken along line I-I′ of FIG. 2. FIG. 3 schematically illustrates one sub-pixel illustrated in FIG. 1.

Referring to FIGS. 1 and 3, the light emitting display apparatus (or the light emitting display panel) 10 according to one or more embodiments of the present disclosure may include a substrate 100, a pixel part 110, a gate driving circuit 120, a dam part 140, and an encapsulation part 150.

The substrate 100 includes thin film transistors, and may be a transistor array substrate, a lower substrate, a base substrate, or a first substrate. The substrate 100 may include a display area DA and a non-display area NDA. The non-display area NDA may include a first non-display area NDA1 extending from the display area DA and a second non-display area NDA2 extending from the first non-display area NDA1. For example, the substrate 100 may be a transparent glass substrate or a transparent plastic substrate.

The pixel part 110 may include a buffer layer 111, a light blocking layer BSM, a pixel circuit layer PCL, an overcoat layer 115, and a light emitting device layer 118.

The buffer layer 111 may be disposed on the substrate 100. The buffer layer 111 may prevent a material of the substrate 100 from being diffused to a transistor in performing a high temperature process in a manufacturing process of the thin film transistor, or may prevent external water or moisture from penetrating into the light emitting device layer 118.

The buffer layer 111 may include a first buffer layer 111a and a second buffer layer 111b.

The first buffer layer 111a may be disposed on the substrate 100. The first buffer layer 111a may be disposed over an entire upper surface of the substrate 100. The first buffer layer 111a may be disposed between the substrate 100 and the pixel circuit layer PCL.

The second buffer layer 111b may be disposed on the first buffer layer 111a. The second buffer layer 111b may be disposed to cover the light blocking layer BSM. The second buffer layer 111b may be configured between the light blocking layer BSM and an active layer ACT. The second buffer layer 111b may be configured between a first light blocking layer BSM1 and the active layer ACT of the pixel circuit PC. The second buffer layer 111b may be configured between a second light blocking layer BSM2 and the active layer ACT of the gate driving circuit 120.

The light blocking layer BSM may be configured between the first buffer layer 111a and the second buffer layer 111b. The light blocking layer BSM may include the first light blocking layer BSM1 and the second light blocking layer BSM2.

The first light blocking layer BSM1 may be disposed at the display area DA. The first light blocking layer BSM1 may be disposed under the pixel circuit PC. The first light blocking layer BSM1 may be configured to prevent changes in the threshold voltage Vth of thin film transistors in the pixel circuit PC caused by external light incident from outside the display panel.

The second light blocking layer BSM2 may be disposed at the non-display area NDA. The second light blocking layer BSM2 may be disposed under the gate driving circuit 120. The second light blocking layer BSM2 may be configured to prevent changes in the threshold voltage Vth of thin film transistors in the gate driving circuit 120 caused by external light incident from outside the display panel.

The pixel circuit layer PCL may be disposed at the display area DA on the substrate 100. The pixel circuit layer PCL may be disposed on the second buffer layer 111b. The pixel circuit layer PCL may include the pixel driving lines including the gate lines GL and the data lines DL which are configured at the display area DA. The pixel circuit layer PCL may include the pixel circuit PC connected to the gate lines GL and the data lines DL. The pixel circuit PC may include a driving thin film transistor TFT which is disposed at a pixel area (or a sub-pixel area) on the substrate 100 or on the second buffer layer 111b.

The driving thin film transistor TFT may include an active layer ACT, a gate electrode GE, a source electrode SE, and a drain electrode DE.

The active layer ACT may be disposed on the substrate 100 or the second buffer layer 111b. For example, the active layer ACT may include a semiconductor material based on metal oxide such as indium-gallium-zinc-oxide (IGZO), but is not limited thereto, and may include a semiconductor material based on silicon such as amorphous silicon or polycrystalline silicon. For example, the active layer ACT may be formed in a patterned shape by depositing a semiconductor material on the second buffer layer 111b, performing a heat treatment process (or an annealing process) for stabilization, and performing a patterning process of the semiconductor material.

The active layer ACT may include a source region, a drain region, and a channel region between the source region and the drain region. The active layer ACT may be covered by a first insulating layer (or a gate insulating layer) 112.

The first insulating layer 112 may be configured in an island shape on only the channel region of the active layer ACT, or may be configured to cover an entire front surface of the buffer layer 111 or the substrate 100 including the active layer ACT. The first insulating layer 112 may be configured as an inorganic material, but is not limited thereto, and may be configured as an organic material.

The gate electrode GE may be disposed on the first insulating layer 112 to overlap the channel region of the active layer ACT. The gate electrode GE may be formed of a gate metal material. The gate electrode GE may be formed using a same process as the gate line GL described above with reference to FIG. 1.

The gate electrode GE may be covered by a second insulating layer (or an interlayer insulating layer) 113. The second insulating layer 113 may be formed on the first insulating layer 112 to cover the gate electrode GE. The second insulating layer 113 may be configured as an inorganic material, but is not limited thereto, and may be configured as an organic material.

The source electrode SE may be disposed on the second insulating layer 113 to be electrically connected to the source region of the active layer ACT. The source electrode SE may be electrically connected to the source region of the active layer ACT through a contact hole formed in the first insulating layer 112 and the second insulating layer 113 overlapping the source region of the active layer ACT.

The drain electrode DE may be disposed on the second insulating layer 113 to be electrically connected to the drain region of the active layer ACT. The drain electrode DE may be electrically connected to the drain region of the active layer ACT through a contact hole formed in the first insulating layer 112 and the second insulating layer 113 overlapping the drain region of the active layer ACT.

The source electrode SE and the drain electrode DE may be formed of a source/drain metal material. For example, the source electrode SE and the drain electrode DE may be configured as a same or different conductive materials as the gate electrode GE. The source electrode SE and the drain electrode DE may be formed together with the data line DL described above with reference to FIG. 1.

The pixel circuit PC may further include at least one switching thin film transistor and at least one capacitor, which are disposed at the pixel area. The at least one switching thin film transistor and the at least one capacitor may be formed together with the driving thin film transistor TFT.

A passivation layer 114 may be disposed at the display area DA and the first non-display area NDA1. The passivation layer 114 may be disposed on the pixel circuit layer PCL. The pixel circuit PC may be covered by the passivation layer 114. The passivation layer 114 may be configured over the gate driving circuit 120. The passivation layer 114 may cover the gate driving circuit 120. The passivation layer 114 may be configured as an inorganic material, but is not limited thereto, and may also be configured as an organic material. The passivation layer 114 may be omitted.

The overcoat layer 115 may be disposed at the display area DA and the first non-display area NDA1. The overcoat layer 115 may be disposed on the passivation layer 114. The overcoat layer 115 may be disposed on the pixel circuit layer PCL. The pixel circuit PC may be covered by the overcoat layer 115. The overcoat layer 115 may be configured over the gate driving circuit 120. The overcoat layer 115 may cover the gate driving circuit 120. For example, the overcoat layer 115 may be configured to planarize a top surface of the pixel circuit PC and the gate driving circuit 120 and may be to protect the pixel circuit PC and the gate driving circuit 120. The overcoat layer 115 may be configured as an organic material. For example, the overcoat layer 115 may be formed of an organic material including acrylic resin, epoxy resin, phenolic resin, polyamide resin, or polyimide resin.

The light emitting device layer 118 may be configured on the overcoat layer 115. The light emitting device layer 118 may be electrically connected to the driving thin film transistor TFT or the pixel circuit PC on the overcoat layer 115.

The light emitting device layer 118 may include a first electrode 118a, a light emitting device 118b, and a second electrode 118c.

The first electrode 118a may be disposed in a patterned shape on the overcoat layer 115. The first electrode 118a may be electrically connected to a source electrode SE of the driving thin film transistor TFT through an electrode contact hole formed in the overcoat layer 115.

The first electrode 118a may be an anode electrode (or a cathode electrode). For example, when the light emitting display apparatus 10 according to one or more embodiments of the present disclosure has a top emission structure, the first electrode 118a may be a reflective electrode that reflects light. When the light emitting display apparatus 10 according to one or more other embodiments of the present disclosure has a bottom emission structure, the first electrode 118a may be a transparent electrode that transmits light.

The light emitting device 118b may be disposed on the first electrode 118a. The light emitting device 118b may include one or more emission structures which is stacked on the first electrode 118a in the order or reverse order of a hole layer, a light emitting layer, and an electron layer. For example, the light emitting device 118b may be implemented to generate color light corresponding to a corresponding sub-pixel. For example, when the unit pixel includes red, green, and blue sub-pixels, the light emitting device 118b of the red sub-pixel may generate red light, the light emitting device 118b of the green sub-pixel may generate green light, and the light emitting device 118b of the blue sub-pixel may generate blue light.

The second electrode 118c may be disposed on the light emitting device 118b. The second electrode 118c may be disposed on the light emitting device 118b so as to face the first electrode 118a with the light emitting device 118b therebetween.

The second electrode 118c may be a cathode electrode (or an anode electrode). For example, when the light emitting display apparatus 10 according to one or more embodiments of the present disclosure has the top emission structure, the second electrode 118c may be a transparent electrode that transmits light. When the light emitting display apparatus 10 according to one or more other embodiments of the present disclosure has the bottom emission structure, the second electrode 118c may be a reflective electrode that reflects light.

The light emitting display apparatus 10 according to one or more embodiments of the present disclosure may further include a bank 117.

The bank 117 may define an opening portion (or an emission region) of the sub-pixel SP and may be disposed to cover an edge portion of the first electrode 118a. For example, the bank 117 may be disposed on the overcoat layer 115 so as to cover only the edge portion except for a central portion of the first electrode 118a. For example, the bank 117 may be formed of an organic material or an inorganic material, and may include a light-absorbing material including a black pigment.

The light emitting device 118b may be disposed only in the opening portion of each sub-pixel SP provided by the bank 117, or may be disposed on the bank 117 and the opening portion of each sub-pixel SP.

The light emitting display apparatus 10 according to one or more embodiments of the present disclosure may further include a spacer 119.

The spacer 119 may be disposed at the first non-display area NDA1. The spacer 119 may be disposed over the bank 117. The spacer 119 may be disposed at a portion of a top portion of the bank 117. The spacer 119 may be disposed at an area where the light emitting device layer 118 is not disposed. The light emitting device 118b and the second electrode 118c may be disposed at one side of the spacer 119. The light emitting device 118b and the second electrode 118c may not be disposed at a top portion of the spacer 119. The spacer 119 may be configured to prevent direct contact between a screen mask and the substrate 100 (or the bank 117) during the deposition process of the light emitting device 118b.

The gate driving circuit 120 may be configured at the non-display area NDA of the substrate 100. The gate driving circuit 120 may be configured at the first non-display area NDA1 of the substrate 100. As illustrated in FIG. 1, the gate driving circuit 120 may be connected to gate lines GL configured at the display area DA. The gate driving circuit 120 may be formed as an integrated circuit at the first non-display area NDA1 of the substrate 100 together with the manufacturing process of the pixel circuit PC, that is, the manufacturing process of the thin film transistors.

The gate driving circuit 120 may generate the gate signals (or scan signals) based on the gate control signals supplied from the panel driving circuit part 300 and output the gate signals in a predetermined order, thereby driving each of the plurality of gate lines GL in the predetermined order.

The light emitting display apparatus 10 according to one or more embodiments of the present disclosure may further include a common power line CPL. The common power line CPL may be disposed at the second non-display area NDA2 of the substrate 100. The common power line CPL may include a same material as source or drain electrodes which is disposed in the display area DA, but is not limited thereto. The common power line CPL may be electrically connected to the second electrode 118c.

The dam part 140 may be disposed at the non-display area NDA of the substrate 100. The dam part 140 may be disposed at the second non-display area NDA2 of the substrate 100. The dam part 140 may be disposed outside the common power line CPL. The dam part 140 may be located at an outermost portion of the substrate 100. The dam part 140 may be disposed to surround the display area DA. The dam part 140 may be configured to prevent overflow of an organic material configuring the encapsulation part 150 to the outermost portion of the substrate 100.

According to one or more embodiments of the present disclosure, the dam part 140 may include first to third dams 141, 412, and 143.

A plurality of first dams 141 may be provided. Each of the plurality of first dams 141 may be disposed between the common power line CPL and the second dam 142, and between the second dam 142 and the third dam 143. Each of the plurality of first dams 141 may be configured as a single layer. Each of the plurality of first dams 141 may be formed through a same process as the bank 117 and may include a same organic material.

The second dam 142 may be disposed between the first dam 141 and the third dam 143. The second dam 142 may have a stacked structure. For example, the second dam 142 may include a sequentially stacked a 2-1^{th} dam 142a and a 2-2^{th} dam 142b. For example, the 2-1^{th} dam 142a may be formed through the same process as the bank 117 and may include the same organic material. For example, the 2-2^{th} dam 142b may be formed through a same process as the spacer 119 and may include a same organic material.

According to one or more embodiments of the present disclosure, the second dam 142 may be thicker than the first dam 141. For example, a distance from the substrate 100 to the second dam 142 may be greater than a distance from the substrate 100 to the first dam 141. Accordingly, the second encapsulation part 152 (or the organic material layer) formed subsequently may be configured to cover the common power line CPL and the first dam 141 between the common power line CPL and the second dam 142. For example, the second encapsulation part 152 (or organic material layer) formed subsequently may be disposed at one side surface of the second dam 142 and may not be disposed at an upper surface of the second dam 142. For example, the second encapsulation part 152 (or organic material layer) may not overlap an upper surface of the second dam 142, the first dam 141 which is disposed between the second dam 142 and the third dam 143, and the third dam 143.

Accordingly, the light emitting display apparatus 10 according to one or more embodiments of the present disclosure may include the second dam 142, and thus, the second encapsulation part 152 (or the organic material layer) may be prevented from overflowing to the outermost portion of the substrate 100.

The third dam 143 may be disposed at the outermost portion of the substrate 100. For example, the third dam 143 may have a stacked structure. For example, the third dam 143 may include sequentially stacked 3-1^{th} dam to 3-3^{th} dam 143a, 143b, and 143c. For example, the 3-1^{th} dam 143a may be formed through a same process as the overcoat layer 115 and may include a same organic material. For example, the 3-2^{th} dam 143b may be formed through the same process as a bank 117 and may include a same organic material. For example, the 3-3^{th} dam 143c may be formed through a same process as a spacer 119 and may include a same organic material.

According to one or more embodiments of the present disclosure, the light emitting display apparatus 10 may include the third dam 143, and thus, the second encapsulation part 152 (or organic material layer) may be further prevented from overflowing to the outermost portion of the substrate 100.

The first to third dams 141, 142, and 143 may have different thicknesses or different heights. For example, a distance from the substrate 100 to the upper surface of each of the first to third dams 141, 142, and 143 may be different from one another. The first to third dams 141, 142, and 143 may be spaced apart by a predetermined distance.

According to one or more embodiments of the present disclosure, the light emitting display apparatus 10 may include the first to third dams 141, 142, and 143, and thus, when a crack occurs in the first encapsulation part 151, the third encapsulation part 153, or the second encapsulation part 152 (or organic material layer) configuring the encapsulation part 150, the crack may be prevented from propagating toward the display panel. Accordingly, penetration of hydrogen and moisture into the light emitting display apparatus 10 may be prevented.

The encapsulation part (or an encapsulation layer) 150 may be configured to cover or surround the pixel part 110. For example, the encapsulation part 150 may be disposed over the light emitting device layer 118 and cover or surround the light emitting device layer 118. The encapsulation part 150 may be configured to protect the pixel part 110. For example, the encapsulation part 150 may be configured to prevent hydrogen or moisture from the outside from penetrating into the light emitting structure of the pixel part 110.

The encapsulation part 150 may include one or more encapsulation parts. For example, the encapsulation part 150 may include one or more inorganic material layers and one or more organic material layers on the light emitting device layer 118. For example, the encapsulation part 150 may include the first encapsulation part 151, the second encapsulation part 152, and the third encapsulation part 153.

The first encapsulation part 151 may be disposed at the display area DA and the non-display area NDA to cover the light emitting device layer 118. The first encapsulation part 151 may be disposed to cover the second electrode 118c. The first encapsulation part 151 may extend from the display area DA and may be disposed in the non-display area NDA to cover the spacer 119, the bank 117, the overcoat layer 115, the common power line CPL, and the dam part 140. For example, the first encapsulation part 151 may be an inorganic material layer.

The second encapsulation part 152 may be disposed on the first encapsulation part 151. The second encapsulation part 152 may extend from the display area DA to one side surface of the second dam 142 in the non-display area NDA. The second encapsulation part 152 may extend from the display area DA to the one side surface of the second dam 142 and may not be configured (or disposed) on the upper surface of the second dam 142. For example, the second encapsulation part 152 may be an organic material layer.

The third encapsulation part 153 may be disposed on the first encapsulation part 151 and the second encapsulation part 152. The third encapsulation part 153 may be disposed on the first encapsulation part 151 and the second encapsulation part 152 which are configured (or disposed) at the display area DA. The third encapsulation part 153 may be disposed on the first encapsulation part 151 and the second encapsulation part 152 which are configured (or disposed) at the non-display area NDA. For example, the third encapsulation part 153 may be an inorganic material layer.

The first encapsulation part 151 and the third encapsulation part 153 may be connected to (or in contact with) each other at the upper surface of the second dam 142. The first encapsulation part 151 and the third encapsulation part 153 may cover the second dam 142, the first dam 141 between the second dam 142 and the third dam 143, and the third dam 143. The first encapsulation part 151 and the third encapsulation part 153 may be connected to (or in contact with) each other at an upper portion of the second dam 142, the first dam 141 between the second dam 142 and the third dam 143, and the third dam 143.

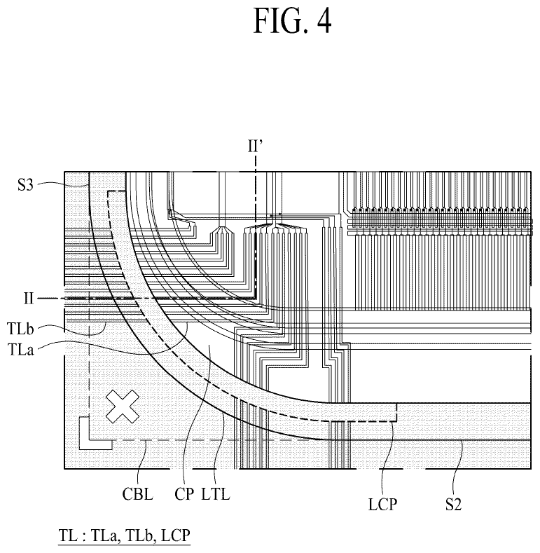

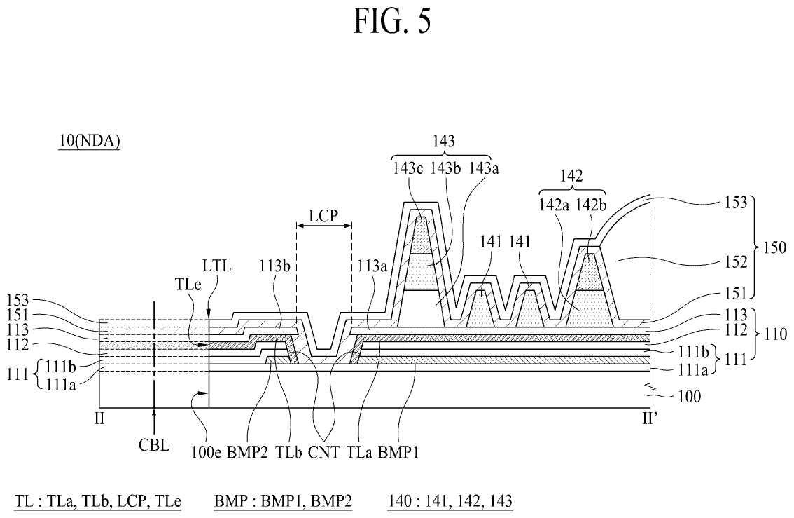

FIG. 4 is an enlarged view schematically illustrating portion ‘A’ illustrated in FIG. 1. FIG. 5 is a cross-sectional view taken along line II-II′ of FIG. 4 according to one or more embodiments of the present disclosure.

Referring to FIGS. 1, 4, and 5, the light emitting display apparatus (or light emitting display panel) 10 according to one or more embodiments of the present disclosure may include a plurality of test lines TL. The gate driving circuit 120 may include a plurality of test lines TL connected to an end (or an end part) of the gate driving circuit 120 for an inspection process performed before formation (or deposition) of the light emitting device layer and the encapsulation part.

The plurality of test lines TL may be disposed at a corner portion CP of the substrate 100. The plurality of test lines TL may be disposed at the corner portion CP between the second long-side S2 and the first short-side S3 of the substrate 100. For example, the corner portion CP may be an area (or a connection region) between the second long-side S2 and the first short-side S3.

The plurality of test lines TL may be connected to the gate driving circuit 120. Each of the plurality of test lines TL may be configured together with the gate lines GL illustrated in FIG. 1. Each of the plurality of test lines TL may be disposed at a same layer as the gate lines GL. Each of the plurality of test lines TL may include a same material as the gate lines GL.

An end (or an end part) TLe of each of the plurality of test lines TL may be exposed at an outer side surface (or an outer sidewall) of the substrate 100. The end TLe of each of the plurality of test lines TL may be exposed at the outer side surface (or outer sidewall) of the corner portion CP between the second long-side S2 and the first short-side S3 of the substrate 100.

For example, the plurality of test lines TL for inspecting the gate driving circuit 120 may extend to an outer part of the laser trimming line LTL, be connected to an inspection part (or a test part), and perform driving of the gate control signal line and ART (Auto Resistance Tester) inspection. Subsequently, using a scribing process, the substrate 100 may be cut along a scribing line CBL defined at the outer part of the substrate 100, and the substrate 100 may be trimmed along a laser trimming line LTL defined at the outer part of the substrate 100 using a laser trimming process. In another example, the laser trimming line LTL may be a grinding line, and the substrate 100 may be cut along the scribing line CBL defined at the outer part of the substrate 100 using a scribing process, and ground along a grinding line defined at the outer part of the substrate 100 using a grinding process.

Accordingly, an end of the corner portion CP of the substrate 100 may be configured (or formed) to have a curvature. Furthermore, the end TLe of each of the plurality of test lines TL may be exposed at the outer side surface (or outer sidewall) of the corner portion CP between the second long-side S2 and the first short-side S3 of the substrate 100. According to one or more embodiments of the present disclosure, a bezel width of the substrate 100 is reduced through the scribing process and the trimming process.

According to one or more embodiments of the present disclosure, each of the plurality of test lines TL may include a line disconnection part LCP formed between the end TLe and the gate driving circuit 120. The line disconnection part LCP may be a region where the plurality of test lines TL are cut (disconnected). For example, the line disconnection part LCP mat be a disconnection part, a cutting part, a line cut part, or lone open part.

Each of the plurality of test lines TL according to one or more embodiments of the present disclosure may include a first line part TLa and a second line part TLb disconnected (or cut) by the line disconnection part LCP. The line disconnection part LCP may be a spaced region in which the first line part TLa and the second line part TLb are spaced apart from each other. The line disconnection part LCP may be an insulated region where the first line part TLa and the second line part TLb are electrically insulated (or isolated) from each other.

The first line part TLa may be connected to the gate driving circuit 120 illustrated in FIG. 1. One end of the first line part TLa may be connected to the gate driving circuit 120, and the other end of the first line part TLa may be disposed adjacent to the line disconnection part LCP. The first line part TLa may be disconnected or insulated from the second line part TLb by the line disconnection part LCP. The first line part TLa may be spaced apart from each other the second line part TLb by the line disconnection part LCP.

The second line part TLb may be disconnected from the first line part TLa by the line disconnection part LCP. The second line part TLb may include an end TLe which is exposed at the outer side surface 100e of the substrate 100. One end of the second line part TLb may be disposed adjacent to the line disconnection part LCP, and the other end TLe of the second line part TLb different from the one end of the second line part TLb may be exposed at the outer side surface 100e of the substrate 100. The end TLe which is exposed at the outer side surface 100e of the substrate 100 may be an outermost side surface (or an outermost sidewall) of the light emitting display apparatus 10.

According to one or more embodiments of the present disclosure, the light emitting display apparatus 10 may further include a first insulating layer 112 and a bridge metal pattern BMP.

The first insulating layer 112 may be disposed between the plurality of test lines TL and the substrate 100. The first insulating layer 112 may extend from the display area DA to the non-display area NDA of the substrate 100. The first insulating layer 112 may include a contact hole CNT overlapping the line disconnection part LCP of each of the plurality of test lines TL. The one end of the first line part TLa adjacent to the line disconnection part LCP may be disposed at or in contact with one side surface of the contact hole CNT which is configured (or formed) at the first insulating layer 112. The one end of the second line part TLb adjacent to the line disconnection part LCP may be disposed at or in contact with the other side surface of the contact hole CNT which is configured (or formed) at the first insulating layer 112.

The second buffer layer 111b may be disposed below (or under) the first insulating layer 112. The second buffer layer 111b may extend from the display area DA to the non-display area NDA of the substrate 100. The second buffer layer 111b may include the contact hole CNT overlapping the line disconnection part LCP of each of the plurality of test lines TL. The one end of the first line part TLa adjacent to the line disconnection part LCP may be disposed at or in contact with the one side surface of the contact hole CNT which is configured (or formed) at the second buffer layer 111b. The one end of the second line part TLb adjacent to the line disconnection part LCP may be disposed at or in contact with the other side surface of the contact hole CNT which is configured (or formed) at the second buffer layer 111b.

The bridge metal pattern BMP may be disposed between the substrate 100 and the first insulating layer 112. The bridge metal pattern BMP may be disposed between the substrate 100 and the second buffer layer 111b. A plurality of bridge metal patterns BMP may be configured (or formed) at a same layer as the light blocking layer BSM illustrated in FIG. 3 and may include a same material. The plurality of bridge metal patterns BMP may be formed using a same process as the light blocking layer BSM.

According to one or more embodiments of the present disclosure, in the inspection process performed before formation (or deposition) of the light emitting device layer and the encapsulation part, by performing some inspection (or ART (Auto Resistance Tester) inspection) using the bridge metal pattern BMP as a bypass lines (or wires), and removing a portion of the bridge metal pattern BMP after the inspection process, and thus, moisture penetration toward the test lines TL may be further prevented.

According to one or more embodiments of the present disclosure, the bridge metal pattern BMP may include a first bridge metal pattern BMP1 and a second bridge metal pattern BMP2. The line disconnection part LCP of each of the plurality of test lines TL may be disposed between the first bridge metal pattern BMP1 and the second bridge metal pattern BMP2. The first bridge metal pattern BMP1 and the second bridge metal pattern BMP2 may be disconnected or insulated from each other with the line disconnection part LCP therebetween. The first bridge metal pattern BMP1 and the second bridge metal pattern BMP2 may be spaced apart from each other with the line disconnection part LCP therebetween.

The first bridge metal pattern BMP1 may be connected to the first line part TLa. The first line part TLa may be electrically connected to the first bridge metal pattern BMP1 through the contact hole CNT of the first insulating layer 112 and the second buffer layer 111b. The first line part TLa may contact (or directly contact) the first bridge metal pattern BMP1 through the one side surface of the contact hole CNT configured (or formed) at the first insulating layer 112 and the second buffer layer 111b. The first line part TLa surrounds one side surface of the contact hole CNT and is connected to the first bridge metal pattern BMP1.

The second bridge metal pattern BMP2 may be connected to the second line part TLb. The second line part TLb may be electrically connected to the second bridge metal pattern BMP2 through the contact hole CNT of the first insulating layer 112 and the second buffer layer 111b. The second line part TLb may contact (or directly contact) the second bridge metal pattern BMP2 through the other side surface of the contact hole CNT configured (or formed) at the first insulating layer 112 and the second buffer layer 111b. The second line part TLb surrounds the other side surface of the contact hole CNT different from the one side surface of the contact hole CNT and is connected to the second bridge metal pattern BMP2.

According to one or more embodiments of the present disclosure, the light emitting display apparatus 10 may further include a second insulating layer 113. The second insulating layer 113 may extend from the display area DA to the non-display area NDA of the substrate 100. The second insulating layer 113 may be (or may correspond to) the second insulating layer 113 or the gate insulating layer illustrated in FIG. 3. The second insulating layer 113 may be disposed at an upper portion of each of the plurality of test lines TL. The second insulating layer 113 may include a 2-1^{th} insulating layer 113a over the first line part TLa and a 2-2^{th} insulating layer 113b over the second line part TLb. The 2-1^{th} insulating layer 113 a and the 2-2th insulating layer 113b may be spaced apart from each other with the line disconnection part LCP therebetween. The 2-1^{th} insulating layer 113a and the 2-2^{th} insulating layer 113b may be in non-contact with the line disconnection part LCP therebetween.

An end of the 2-1^{th} insulating layer 113a adjacent to the line disconnection part LCP may protrude toward the 2-2^{th} insulating layer 113b than the first line part TLa. An end of the 2-2^{th} insulating layer 113b adjacent to the line disconnection part LCP may protrude toward the 2-1^{th} insulating layer 113a than to the second line part TLb.

According to one or more embodiments of the present disclosure, the light emitting display apparatus 10 may include an encapsulation part 150. Since the encapsulation part 150 has been described above with reference to FIG. 3, hereinafter, only different elements will be mainly described,

Referring to FIGS. 3 and 5, the encapsulation part 150 may be configured to cover the light emitting device layer 118 at the display area DA and to cover the line disconnection part LCP of each of the plurality of test lines TL at the non-display area NDA. The first encapsulation part 151 and the third encapsulation part 153 among the encapsulation part 150 may be disposed over the display area DA and the non-display area NDA of the substrate 100. For example, the first encapsulation part 151 and the third encapsulation part 153 may be disposed on an entire surface of the display area DA and the non-display area NDA of the substrate 100. In the non-display area NDA, the encapsulation part 150 may be disposed on the second insulating layer 113. In the non-display area NDA, the encapsulation part 150 may be configured to cover the second insulating layer 113.

The first encapsulation part 151 of the encapsulation part 150 may extend from the display area DA to the non-display area NDA and may be disposed over the substrate 100. For example, the first encapsulation part 151 may be disposed on an entire surface of the substrate 100. The first encapsulation part 151 may cover the line disconnection part LCP of each of the plurality of test lines TL. The first encapsulation part 151 may be configured to cover the upper portion of the plurality of test lines TL so that the plurality of test lines TL are not exposed. The first encapsulation part 151 may contact (or directly contact) the buffer layer (or the first buffer layer 111a) through the line disconnection part LCP of each of the plurality of test lines TL. The first buffer layer 111a may be disposed between the substrate 100 and the bridge metal pattern BMP.

The second encapsulation part 152 of the encapsulation part 150 may be configured (or formed) at one side surface of the second dam 142, and may not be configured (or formed) at an upper surface of the second dam 142 and the third encapsulation part 153. For example, the second encapsulation part 152 may not overlap the upper surface of the second dam 142, the first dam 141 disposed between the second dam 142 and the third dam 143, or the third dam 143.

The third encapsulation part 153 of the encapsulation part 150 may extend from the display area DA to the non-display area NDA and may be disposed over the substrate 100. For example, the third encapsulation part 153 may be disposed on an entire surface of the substrate 100. The third encapsulation part 153 may be configured to cover the first encapsulation part 151. The third encapsulation part 153 may contact (or directly contact) the first encapsulation part 151 at the upper surface of the second dam 142 where the second encapsulation part 152 is not configured (or formed), the first dam 141 disposed between the second dam 142 and the third dam 143, and an upper surface of the third dam 143.

The third encapsulation part 153 may be configured to cover the line disconnection part LCP of each of the plurality of test lines TL. The third encapsulation part 153 may be configured to additionally cover the upper portion of the plurality of test lines TL so that the plurality of test lines TL are not exposed.

According to one or more embodiments of the present disclosure, the light emitting display apparatus 10 may include the line disconnection part LCP, and thus, a moisture permeable path of the light emitting display apparatus 10 may be blocked, penetration of hydrogen and moisture may be prevented, and deterioration of the light emitting display apparatus 10 or the light emitting device may be prevented.

According to one or more embodiments of the present disclosure, the moisture permeable path of the light emitting display apparatus 10 may be blocked, the light emitting display apparatus 10 with improved reliability may be provided, a long lifespan may be realized, and low-power driving may be possible.

The light emitting display apparatus 10 according to one or more embodiments of the present disclosure may be implemented through the following process.

First, the first buffer layer 111a, the bridge metal pattern BMP, the second buffer layer 111b, and the first insulating layer 112 may be sequentially configured (or formed) on the substrate 100. Next, the second buffer layer 111b and the first insulating layer 112 may be dry-etched to form the contact holes CNT. Next, the test lines TL may be formed to be connected to the bridge metal pattern BMP through the contact holes CNT. Then, the second insulating layer 113 may be configured (or formed) on the test lines TL. The second insulating layer 113 may be patterned through dry etching. Accordingly, the second insulating layer 113 may include the 2-1^{th} insulating layer 113a and the 2-2^{th} insulating layer 113b, and the end of the 2-1^{th} insulating layer 113a and the end of the 2-2^{th} insulating layer 113b adjacent to the line disconnection part LCP may protrude toward the line disconnection part LCP.

Then, the inspection part may be connected to the test lines TL, and driving of the gate control signal lines and ART (Auto Resistance Tester) inspection process may be performed. Next, if no defect is detected during the inspection process, the test lines TL and the bridge metal pattern BMP may be etched using a wet etching process. Accordingly, the first and second line parts TLa and TLb may be configured (or formed). Further, the bridge metal pattern BMP connected to the test lines TL may be used as a bypass wiring for inspection process, and after the inspection, the portion of the bridge metal pattern BMP overlapping the line disconnection part LCP and connected to the test lines TL may be etched, thereby blocking moisture permeation path. Then, the encapsulation part 150 may be configured (or formed) over the second insulating layer 113 to cover the line disconnection part LCP.

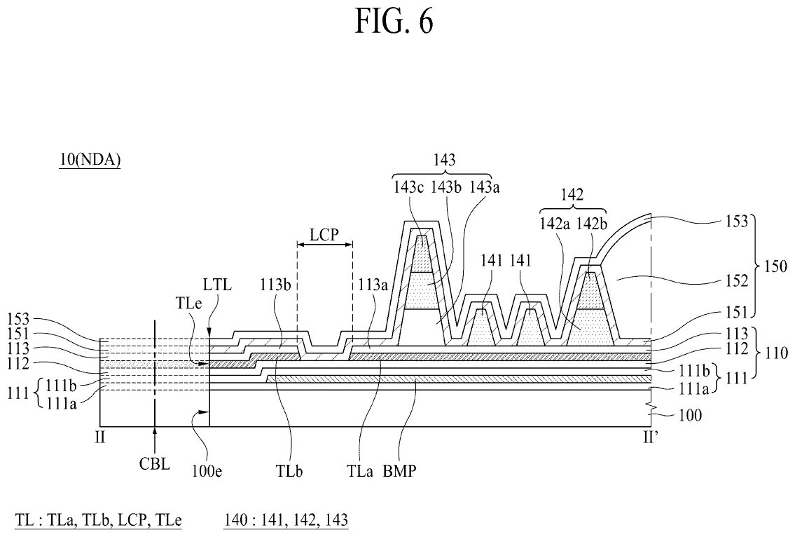

FIG. 6 is a cross-sectional view taken along line II-II′ of FIG. 4 according to one or more other embodiments of the present disclosure. FIG. 6 illustrates one or more embodiments implemented by modifying a configuration of the plurality of test lines, the line disconnection part, and the bridge electrodes in an embodiment of the present disclosure illustrated in FIG. 5. Hereinafter, therefore, only different elements will be mainly described, like reference numerals refer to like elements, and their repetitive descriptions may be omitted.

Referring to FIGS. 1, 4, and 6, the light emitting display apparatus (or light emitting display panel) 10 according to one or more other embodiments of the present disclosure may include a plurality of test lines TL. Each of the plurality of test lines TL may include a first line part TLa and a second line part TLb which are disconnected by the line disconnection part LCP.

The light emitting display apparatus 10 may further include a first insulating layer 112, a second insulating layer 113, and a bridge metal pattern BMP.

The first insulating layer 112 may be disposed between the plurality of test lines TL and the substrate 100. The first insulating layer 112 may extend from the display area DA to the non-display area NDA of the substrate 100. The first insulating layer 112 may overlap the line disconnection part LCP. The plurality of test lines TL may be configured (or disposed) over the first insulating layer 112 and may contact (or directly contact) an upper surface of the first insulating layer 112. The first line part TLa and the second line part TLb may be spaced apart from each other over the first insulating layer 112.

The second buffer layer 111b may be disposed below (or under) the first insulating layer 112. The second buffer layer 111b may extend from the display area DA to the non-display area NDA of the substrate 100. The second buffer layer 111b may overlap the line disconnection part LCP. The first line part TLa and the second line part TLb may be spaced apart from each other over the second buffer layer 111b.

The bridge metal pattern BMP may be disposed between the substrate 100 and the first insulating layer 112. The bridge metal pattern BMP may be disposed between the substrate 100 and the second buffer layer 111b. The bridge metal pattern BMP may overlap the line disconnection part LCP. The first line part TLa and the second line part TLb may be spaced apart from each other over the bridge metal pattern BMP.

According to one or more other embodiments of the present disclosure, the light emitting display apparatus 10 may further include the second insulating layer 113. The second insulating layer 113 may include a 2-1^{th} insulating layer 113a over the first line part TLa and a 2-2^{th} insulating layer 113b over the second line part TLb. The 2-1^{th} insulating layer 113a and the 2-2^{th} insulating layer 113b may be in non-contact with the line disconnection part LCP therebetween.

An end of the first line part TLa adjacent to the line disconnection part LCP may protrude toward the second line part TLb than to an end of the 2-1^{th} insulating layer 113a. An end of the second line part TLb adjacent to the line disconnection part LCP may protrude toward the first line part TLa than to an end of the 2-2^{th} insulating layer 113b.

According to one or more other embodiments of the present disclosure, the light emitting display apparatus 10 may include an encapsulation part 150. The encapsulation part 150 may be configured to cover the light emitting element layer 118 in the display area DA and may be configured to cover the line disconnection part LCP of each of the plurality of test lines TL in the non-display area NDA.

A first encapsulation part 151 of the encapsulation part 150 may extend from the display area DA to the non-display area NDA and may be disposed over the substrate 100. For example, the first encapsulation part 151 may be disposed on an entire surface of the substrate 100. The first encapsulation part 151 may be configured to cover the line disconnection part LCP of each of the plurality of test lines TL. The first encapsulation part 151 may be configured to cover an upper surface of the second insulating layer 113. The first encapsulation part 151 may be configured to cover an upper portion of the plurality of test lines TL so that the plurality of test lines TL are not exposed. The first encapsulation part 151 may contact (or directly contact) the first insulating layer 112 through the line disconnection part LCP of each of the plurality of test lines TL.

A third encapsulation part 153 of the encapsulation part 150 may extend from the display area DA to the non-display area NDA and may be disposed over the substrate 100. For example, the third encapsulation part 153 may be disposed on the entire surface of the substrate 100. The third encapsulation part 153 may be configured to cover the first encapsulation part 151. The third encapsulation part 153 may be configured to cover the line disconnection part LCP of each of the plurality of test lines TL. The third encapsulation part 153 may be configured to additionally cover the upper portion of the plurality of test lines TL so that the plurality of test lines TL are not exposed.

According to one or more other embodiments of the present disclosure, the light emitting display apparatus 10 may include the line disconnection part LCP, and thus, a moisture permeable path of the light emitting display apparatus 10 may be blocked, penetration of hydrogen and moisture may be prevented, and deterioration of the light emitting display apparatus 10 or the light emitting device may be prevented.

According to one or more other embodiments of the present disclosure, the moisture permeable path of the light emitting display apparatus 10 may be blocked, the light emitting display apparatus 10 with improved reliability may be provided, a long lifespan may be realized, and low-power driving may be possible.

The light emitting display apparatus 10 according to one or more other embodiments of the present disclosure may be implemented through the following process.

First, the first buffer layer 111a, the bridge metal pattern BMP, the second buffer layer 111b, the first insulating layer 112, the test lines TL, and the second insulating layer 113 may be sequentially configured (or formed) on the substrate 100. Then, the second insulating layer 113 may be patterned through dry etching. Accordingly, the second insulating layer 113 may include the 2-1^{th} insulating layer 113a and the 2-2^{th} insulating layer 113b.

Then, the inspection part may be connected to the test lines TL, and driving of the gate control signal lines and ART (Auto Resistance Tester) inspection process may be performed. According to one or more other embodiments of the present disclosure, the bridge metal pattern BMP is not used as a bypass wiring for inspection process, and the inspection process may be performed using the test lines TL. If no defect is detected during the inspection process, the test lines TL overlapping the line disconnection part LCP may be etched using a dry etching process. Accordingly, the first and second line parts TLa and TLb may be configured (or formed). Then, the encapsulation part 150 may be configured (or formed) over the second insulating layer 113 to cover the line disconnection part LCP. Thus, the moisture penetration path caused by exposed test lines TL may be blocked.

The light emitting display apparatus according to one or more embodiments of the present disclosure may be applied to or included in mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic books, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theatre apparatuses, theatre display apparatuses, TVs, wall paper display apparatuses, signage apparatuses, game machines, notebook computers, monitors, cameras, camcorders, and home appliances, or the like.

It will be apparent to those skilled in the art that various modifications and variations can be made in the present disclosure without departing from the spirit or scope of the present disclosure. Thus, it is intended that the present disclosure covers the modifications and variations of this disclosure provided that within the scope of the claims and their equivalents.

What is claimed is:

1. A light emitting display apparatus, comprising:
a substrate including a display area and a non-display area;
a pixel circuit layer including a pixel driving line and a pixel circuit, the pixel driving line including a gate line and a data line configured at the display area, the pixel circuit connected to the gate line and the data line;
an overcoat layer configured at the display area to cover the pixel circuit layer;
a light emitting device layer configured on the overcoat layer and connected to the pixel circuit;
a gate driving circuit configured at the non-display area and connected to the gate line; and
a plurality of test lines disposed at a corner portion of the substrate and connected to the gate driving circuit,
wherein an end of each of the plurality of test lines is exposed to an outer side surface of the substrate, and
wherein each of the plurality of test lines includes a line disconnection part formed between the end of each of the plurality of test lines and the gate driving circuit.

2. The light emitting display apparatus of claim 1, wherein each of the plurality of test lines is configured together with the gate line.

3. The light emitting display apparatus of claim 1, wherein each of the plurality of test lines is disposed on a same layer as the gate line.

4. The light emitting display apparatus of claim 1, wherein each of the plurality of test lines comprises:
a first line part connected to the gate driving circuit; and
a second line part disconnected from the first line part by the line disconnection part, the second line part having an end exposed to the outer side surface of the substrate.

5. The light emitting display apparatus of claim 4, wherein the line disconnection part is disposed between the first line part and the second line part.

6. The light emitting display apparatus of claim 4, further comprising:
a first insulating layer disposed between the plurality of test lines and the substrate; and
a second insulating layer disposed on the plurality of test lines,
wherein each of the plurality of test lines further comprises a bridge metal pattern disposed between the substrate and the first insulating layer.

7. The light emitting display apparatus of claim 6, wherein the bridge metal pattern comprises:
a first bridge metal pattern connected to the first line part; and
a second bridge metal pattern connected to the second line part, and
wherein the line disconnection part of each of the plurality of test lines is disposed between the first bridge metal pattern and the second bridge metal pattern.

8. The light emitting display apparatus of claim 7, wherein:
the first insulating layer comprises a contact hole overlapping the line disconnection part of each of the plurality of test lines,
the first line part is electrically connected to the first bridge metal pattern through the contact hole of the first insulating layer, and
the second line part is electrically connected to the second bridge metal pattern through the contact hole of the first insulating layer.

9. The light emitting display apparatus of claim 8, wherein:
the first line part surrounds a first side surface of the contact hole, the first line part connected to the first bridge metal pattern, and
the second line part surrounds a second side surface of the contact hole different from the first side surface of the contact hole, the second line part connected to the second bridge metal pattern.

10. The light emitting display apparatus of claim 6, wherein the second insulating layer comprises:
a 2-1^{th} insulating layer over the first line part; and
a 2-2^{th} insulating layer over the second line part, and
wherein the line disconnection part is between the 2-1^{th} insulating layer and the 2-2^{th} insulating layer.

11. The light emitting display apparatus of claim 4, further comprising:
a first insulating layer disposed between the plurality of test lines and the substrate;
a second insulating layer disposed on the plurality of test lines; and
a bridge metal pattern disposed between the substrate and the first insulating layer,
wherein the line disconnection part overlaps the first insulating layer and the bridge metal pattern.

12. The light emitting display apparatus of claim 1, wherein:
the substrate comprises a first long-side, a second long-side parallel to the first long-side, a first short-side, and a second short-side parallel to the first short-side,
the gate driving circuit is configured at the non-display area adjacent to the first short-side of the substrate, and
the plurality of test lines are disposed at the corner portion between the second long-side and the first short-side of the substrate.

13. The light emitting display apparatus of claim 12, wherein the end of each of the plurality of test lines is exposed at the corner portion between the second long-side and the first short-side of the substrate.

14. The light emitting display apparatus of claim 12, wherein the corner portion of the substrate has a curved shape.

15. The light emitting display apparatus of claim 12, further comprising a pad part disposed at a first edge portion adjacent to the first long-side of the substrate, the pad part including a data pad connected to the data line and a gate pad connected to the gate driving circuit.

16. The light emitting display apparatus of claim 1, further comprising an encapsulation part configured to cover the light emitting device layer and to cover the line disconnection part of each of the plurality of test lines.

17. The light emitting display apparatus of claim 16, wherein the encapsulation part comprises:
a first encapsulation part disposed at the display area and the non-display area to cover the light emitting device layer;
a second encapsulation part disposed on the first encapsulation part in the display area; and
a third encapsulation part disposed on the first encapsulation part and the second encapsulation part in the non-display area, and
wherein the first encapsulation part covers the line disconnection part of each of the plurality of test lines.

18. The light emitting display apparatus of claim 17, further comprising a buffer layer disposed between the substrate and the pixel circuit layer,
wherein the first encapsulation part is in contact with the buffer layer through the line disconnection part of each of the plurality of test lines.

19. The light emitting display apparatus of claim 17, further comprising:
a first insulating layer disposed between the plurality of test lines and the substrate,
wherein the first encapsulation part is in contact with the first insulating layer through the line disconnection part of each of the plurality of test lines.
